(19) United States
(12) Patent Application Publication
(10) Pub. No.: US 2021/0048318 A1
(43) Pub. Date: Feb. 18, 2021

(54) SENSOR ARRANGEMENT FOR CAPACITIVE POSITION DETECTION OF AN OBJECT

(71) Applicant: IEE INTERNATIONAL ELECTRONICS & ENGINEERING S.A., ECHTERNACH (LU)

(72) Inventors: Frank ALTHAUS, Saarbrücken (DE); Baptiste ANTI, Hettange-Grande (FR); Thomas FABER, Schweich (DE); Michael PUETZ, Trier (DE); Jan LIPTAK, Vlachovo (SK)

(21) Appl. No.: 17/043,424

(22) PCT Filed: Mar. 28, 2019
(86) PCT No.: PCT/EP2019/057834

§ 371 Date: Sep. 29, 2020

(30) Foreign Application Priority Data
Mar. 30, 2018 (LU) LU100755

(51) Int. Cl. G01D 5/24; H03K 17/96

(52) U.S. Cl. CPC G01D 5/2405; H03K 2217/94036; H03K 17/962

(57) ABSTRACT

A sensor arrangement for capacitive position detection of an object. In order to provide means for hand detection on a steering wheel which are reliable and have a low complexity, the sensor arrangement includes: a sensor line with a plurality of sensor electrodes connected in series, wherein at least one resistive element is effectively connected in series between each two consecutive sensor electrodes, a measurement device connected via a linear, unbranched first connection to a first terminal of the sensor line, wherein the measurement device is configured to apply a time-dependent first signal to the first terminal and to identify an activated sensor electrode, with an object in its proximity, at least partially based on a first voltage-current relation at the first terminal.

### TECHNICAL FIELD

The present invention generally relates to a sensor arrangement for capacitive position detection of an object. The invention further relates to a method for capacitive position detection of an object.

### BACKGROUND

In modern vehicles, it can be necessary to detect whether the driver has his hands on the steering wheel (e.g. in order to determine whether the driver is ready to carry out a steering action). Steering assistance may include an active correction possibility for the driver to be used in certain circumstances. For example, a provision may be made for a steering assistance system to be activated only when the driver has his hands on the steering wheel. In most countries, it is mandatory that the vehicle when moving is under the control of the driver, even if modern assistance systems would be able to safely operate the vehicle autonomously in certain situations.

In order to identify whether or not at least one hand is positioned on the steering wheel, several concepts have been developed. One concept relies on the EPS system and induces a low-amplitude vibration in the steering wheel. If the hands of the driver are on the steering wheel, this has a dampening effect which can be detected. However, the vibration can be distracting or disturbing to the driver. Other systems use dedicated sensors. One such system uses resistive sensor elements where two conductors are disposed spaced apart under the surface of the steering wheel. If a certain pressure is exerted on the surface, the conductors are brought into contact. However, the amount of pressure required to activate the sensor makes this approach less reliable. Another approach uses capacitive sensors, which detect a hand by its influence on an electric field generated by the sensor. While these sensors are more reliable, they considerably increase the complexity of the steering wheel, in particular if the position of the hand is to be detected, which makes it necessary to provide a plurality of sensors, i.e. one for each surface position, along with detection circuitry for each individual sensor. This complexity increases the costs and makes the system more prone to failure.

### SUMMARY

It is thus an object of the present invention to provide means for hand detection on a steering wheel which are reliable and have a low complexity.

This problem is solved by a sensor arrangement and/or method according to the claims.

The invention in at least some embodiments provides a sensor arrangement for capacitive position detection of an object. The sensor arrangement is designed to detect the presence of an object, in particular a hand or a finger of a user, and, more specifically, to detect a position of the object. The sensor arrangement is designed for capacitive detection, which means that the detection of the object is based on measuring a capacitance or, respectively, a quantity that depends on a capacitance.

The sensor arrangement comprises a sensor line with a plurality of sensor electrodes connected in series, wherein at least one resistive element is effectively connected in series between each two consecutive sensor electrodes. Preferably, the sensor line is a series connection of sensor electrodes and at least one resistive element. The sensor electrodes can be made of any kind of conductive material, e.g. metal sheet, conductive foil or the like. In some embodiments, the sensor electrodes can be made of flexible material. The size and shape of the electrodes may be different for different applications. They may be disposed along, on or underneath the surface of a device on which the position of a nearby object needs to be detected. The sensor electrodes can be flat, having a thickness that is much smaller than a length and a width. The number of sensor electrodes in the sensor line may depend on the particular application, but may be e.g. between 2 and 10 or between 3 and 5. It will be noted that the measurement principle and the accuracy are similar as long as the number of measurement channels is n-1 compared to the number n of electrodes. All sensor electrodes are connected in series in a sensor line, which means that a current flowing from one end of the sensor line to the opposite end of the sensor line flows through all sensor electrodes. Each sensor electrode may be associated with a capacitance with respect to ground or a grounded structure.

At least one resistive element is effectively connected in series between each two consecutive sensor electrodes. Each resistive element, of course, has an electrical resistance. With respect to each pair of consecutive (or neighboring) sensor electrodes in the sensor line, at least one resistive element is effectively connected in series between these two sensor electrodes, which means that a current flowing from one sensor electrode to the next sensor electrode flows through the respective resistive element. Furthermore, since at least one resistive element is connected between each pair of consecutive sensor electrodes, the further the two electrodes are apart within the sequence of the sensor electrodes, the higher the number of resistive elements a current has to flow through in between. E.g. when flowing from the “first” electrode to the “second” electrode, the current flows through (at least) one resistive element, while when flowing from the “first” electrode to the “fifth” electrode, a current flows through (at least) 4 resistive elements.

The sensor arrangement further comprises a measurement device that is connected via a linear, unbranched first connection to a first terminal of the sensor line. More specifically, the measurement device may comprise a first electric source (e.g. current source or voltage source) that is connected via the first connection to the first terminal. Here and in the following, the term “measurement device” is not to be construed in any limiting way as to the physical configuration. For instance, the measurement device may comprise a plurality of physically spaced apart components that could be unconnected or connected wirelessly or by wire. At least some aspects of the measurement device may be software-implemented. The measurement device is connected, i.e. electrically connected, to a first terminal of the sensor line, wherein “first terminal” does not imply any kind of sequence but simply serves to distinguish the first terminal of from other terminals that may be present. In general, the first terminal may be located in any part of the sensor line. The first terminal may also be referred to as a “connection point” which serves as the electrical connection between the measurement device and the sensor line. It may be realized by a permanent connection (e.g. by soldering) or by a detachable connection (e.g. plug-and-socket). The measurement device is connected to the first terminal via a linear, unbranched first connection. In other words, there is no circuit or conducting line that branches off from the first connection between the measurement device and the first terminal. Thus, the current at the first electric source is equal to the current at the first terminal. Normally, but not necessarily, the measurement device (and, in particular, the first electric source) is directly connected to the first terminal, with no resistive, inductive or capacitive element in between.

According to at least some embodiments of the invention, the measurement device is configured to apply a time-dependent first signal to the first terminal and to identify an activated sensor electrode, with an object in its proximity, at least partially based on a first voltage-current relation at the first terminal. The first signal may be a voltage signal, i.e. the measurement device may comprise a voltage source that is configured to provide a predetermined voltage. However, the first signal could also be a current signal, if the measurement device comprises a current source that is configured to provide a predetermined current. Either way, the first signal is time-dependent, i.e. it changes as a function of time. In particular, it may be an alternating signal that alternatingly changes its polarity. The signal could be a pulse signal, but normally is a continuous signal.

The measurement device applies the first signal to the first terminal and uses a first voltage-current relation at the first terminal, i.e. a relation between a voltage at the first terminal and a current at the first terminal, to identify an activated sensor electrode. The voltage-current relation could be represented e.g. by an impedance or an admittance. However, if the first signal corresponds to a predefined voltage (or current, respectively), the voltage-current relation is implicitly given by measuring the current (or voltage, respectively). For instance, the measurement device may apply a predetermined voltage and measure the flowing current, whereby the impedance and admittance are implicitly given and may optionally be determined explicitly. It is understood that the impedance as well as the admittance are functions of the frequency of the first signal and if the first signal contains a superposition of different frequencies, a different impedance/admittance applies for each frequency. It should be noted that there is in general a phase shift between the voltage and the current at the first terminal, wherefore the voltage-current relation in general contains information about an amplitude and a phase angle or, respectively, a real part and an imaginary part. For instance, if the current is measured, the measurement has to include the phase shift with respect to the applied voltage or needs to distinguish between a real part of the current (in phase with the voltage) and an imaginary part (with a 90° shift with respect to the voltage).

The measurement device is configured to identify an activated sensor electrode with an object in its proximity. In other words, it identifies (at least) one electrode that has an object in its proximity. An electrode with an object in its proximity is herein referred to as “activated”. The object is nearby, which includes the possibility that the object actually touches the respective electrode, but the electrode is normally electrically isolated from the object e.g. by a layer of isolating material. By identifying the activated sensor electrode, the position of the object is known. The identification of the activated sensor electrode is at least partially based on the first voltage-current relation. When an object is nearby a sensor electrode, an electric field between the electrode and ground is affected. In other words, the capacitance associated with the respective sensor electrode is changed. This, in turn, affects the individual impedance of the respective sensor electrode and thus the first voltage-current relation at the first terminal. However, this effect alone normally does not allow to distinguish between different sensor electrodes. If, for example, all sensor electrodes are designed similarly and have a similar position with respect to ground, the changing capacitance changes the total impedance in (almost) the same way, irrespective which sensor electrode is the one with the nearby object. However, since a resistive element is effectively connected between each two consecutive sensor electrodes, the current flowing between the first terminal and the activated sensor electrode is affected by a number of resistive elements. This number increases with the number of sensor electrodes between the first terminal and the activated sensor electrode. Therefore, the resistance between the first terminal and the activated sensor electrode is different depending on which sensor electrode is activated. This, in principle, allows for an identification of the activated sensor electrode based on the first voltage-current relation. Although the result could be ambiguous in some cases, such ambiguities can normally be avoided by a proper layout of the sensor arrangement and/or optional features which are discussed below.

The great benefit of the inventive sensor arrangement is that it requires only a limited amount of wiring, namely for the connections within the sensor line and for the connection of the measurement device to the first terminal. Also, it requires only one measurement device that only has to apply a single signal. Therefore, the sensor arrangement can be realized in a simple and low-cost manner and with a compact design.

There are various conceivable applications for the inventive sensor arrangement. According to one preferred embodiment, the sensor arrangement is adapted for hand detection in a steering wheel of a vehicle, normally a land vehicle like a car. However, application to other vehicles like sea or air vehicles is also conceivable. In such an embodiment, the first and second electrode and the conducting elements are disposed along a surface of the steering wheel, whereby a position of a hand of a user can be detected. In other words, the detection surface is an outer surface of the steering wheel. The sensor arrangement may in this context also be characterized as a sensor arrangement for hand position detection, since the main purpose is to detect the position of at least one hand of a user (driver) on the steering wheel. It should be noted that a steering wheel could be provided with more than one inventive sensor arrangement, if this is considered advantageous.

In general, the first terminal can be disposed in any location along the sensor line. Preferably, though, the first terminal is an end terminal of the sensor line. In other words, the measurement device is connected to one end of the sensor line, with all sensor electrodes and resistive elements connected successively downstream of the first terminal. This design normally helps to reduce ambiguities since there is for each sensor electrode a unique, individual number of resistive elements connected between this sensor electrode and the first terminal.

It is conceivable that each resistive element is an internal resistance of a sensor electrode. This, however, this would normally require an internal resistance that is considerably higher than typical values for e.g. capacitive sensor electrodes known in the art. If the resistance of the resistive element is rather low, it may be difficult to measure its influence on the first voltage-current relation, thus making it difficult to identify an activated sensor electrode. Preferably, at least one resistive element is a resistor external to the sensor electrodes. In other words, at least one dedicated resistor is connected between two consecutive sensor electrodes. Normally, every resistive element is a resistor. The resistance of the resistor may be chosen e.g. such that it is of the same order of magnitude as typical reactance values of the sensor electrodes.

Preferably, the resistances of all resistive elements differ by less than 20%. This means that the difference between the smallest resistance and the greatest resistance is less than 20% (with respect to the greatest resistance). The difference may even be lower, e.g. less than 10% or less than 5%. In particular, the resistances of all resistive elements may be identical. If the resistance of one resistive element is much greater than the resistance of another resistive element, the influence of the latter resistive element would only have limited influence on the total resistance. In general, the resistances of resistive elements should to be in a range that the voltage—current—phase shift is detectable. The variance of the resistors does not necessarily have to be very accurate as there is always one measurement channel that is direct connected so that the statement above is fulfilled.

According to one embodiment, the measurement device is configured to apply a first voltage as the first signal and to identify the activated sensor electrode at least partially based on a real part and an imaginary part of a first current at the first terminal. In this context, the first voltage is normally a predefined voltage supplied by a first voltage source of the measurement device. The measurement device can measure the first current either at the first terminal or in some other location that is equivalent. Since the first voltage is given, the real part of the first current, which is in phase with the first voltage, and the imaginary part, which is shifted by 90° with respect to the first voltage, can be determined. When viewing the relation between the real part and the imaginary part in a diagram, certain areas can be associated with a specific sensor electrode. The outer limit of a certain area may be described by one or more threshold values for the real part (or the imaginary part, respectively) which in general are a function of the imaginary part (or the real part, respectively). These threshold values may be either calculated by the measurement device based on a formula or they may be stored in a lookup table. It is understood that alternatively, the first signal could be a current signal and the activated sensor electrode could be identified at least partially based on a real part and the imaginary part of a first voltage at the first terminal.

Preferably, the first signal is a sinusoidal signal. Such a signal can be described as a sine wave with no or only negligible upper harmonics. In other words, the first signal has a single frequency, which makes the evaluation of the voltage-current relation easier, since this relation is normally frequency-dependent. Preferably, the frequency is maintained the same for every measurement. However, different frequencies may be used for different measurements.

In some cases, identification of an activated sensor electrode can be inconclusive or ambiguous. This applies in particular to situations where more than one sensor electrode is activated by a nearby object. However, such ambiguities can be resolved. According to a preferred embodiment, the measurement device is connected via a linear, unbranched second connection to a second terminal of the sensor line and is configured to apply a time-dependent second signal to the second terminal and to identify at least one activated sensor electrode at least partially based on a second voltage-current relation at the second terminal. Like the first terminal, the second terminal can be realized by a permanent connection or by a non-permanent connection. It is understood that the second terminal is distinct from the first terminal and there has to be at least one element (a sensor electrode or a resistive element) between the first and the second terminal. The second terminal can be regarded as a different reference point for determining a (second) voltage-current relation. The measurement device is connected to the second terminal via a linear, unbranched second connection. In other words, there is no circuit or conducting line that branches off from the second connection between the measurement device and the second terminal. More specifically, the measurement device may comprise a second electric source (e.g. current source or voltage source) that is connected via the second connection to the second terminal. The current at the second electric source is equal to the current at the second terminal. Normally, but not necessarily, the measurement device (and, in particular, the second electric source) is directly connected to the second terminal. Of course, the measurement principle is the same as with regard to the first terminal and the first signal. Like the first signal, the second signal may be a voltage signal or a current signal. Preferably it is a sinusoidal signal. While the first and the second signal are applied at two different terminals, it is possible that both signals are otherwise identical, having the same waveform, frequency, amplitude, phase etc. Preferably, the measurement device is configured to identify at least one activated sensor electrode based on the first voltage-current relation and the second voltage-current relation. In other words, information gained from measurements regarding both the first and the second terminal are combined.

The second terminal could be an end terminal disposed at one end of the sensor line. Especially in cases where the first terminal is an end terminal, however, a second terminal disposed at the other end of the signal line rarely helps to resolve ambiguities. Therefore, it is preferred that the second terminal is disposed between two sensor electrodes. I.e., the second terminal is electrically connected between these two sensor electrodes. This applies especially, but not exclusively, to a case where the first terminal is an end terminal.

It is also preferred that the first and second terminal are asymmetrically disposed on the sensor line. This means that the number of sensor electrodes between the first terminal and one end of the signal line has to be different from the number of sensor electrodes between the second terminal and the opposite end of the signal line. E.g. if the first terminal is an end terminal, there are zero electrodes between it and one end of the sensor line, wherefore there has to be at least one electrode between the second terminal and the opposite end. With such a configuration, it is normally possible to dissolve any ambiguities arising from two sensor electrodes being activated the same time.

The measurement device can be configured to apply the first signal and the second signal sequentially and/or simultaneously. In one embodiment, the measurement device is configured to apply the first signal and to switch the first signal off before applying the second signal. In another embodiment, both signals are applied simultaneously, which of course leads to a current superposition within the signal line. This, in turn, makes the evaluation of the first and second voltage-current relation a little more complex, but still feasible. There may be also embodiments where the first signal is activated, then the second signal is activated before the first signal is deactivated and after the first signal is deactivated, the second signal is deactivated. Of course, the sequence of the two signals may be inverted, so that the second signal is activated before the first signal. In a further possible embodiment, the two signals may also have different frequencies.

When employing the second signal at the second terminal, the measurement device is preferably configured to identify at least two activated sensor electrodes. In other words, the measurement device can identify two sensor electrodes that simultaneously each have an object in their proximity. This may be the case e.g. when the sensor arrangement is adapted for hand detection in a steering wheel of the vehicle. In this case, it is quite common that the driver touches the steering wheel either with one hand or with both hands, which needs to be safely identified and distinguished.

Preferably, the measurement device is configured to apply a second voltage as the second signal and to identify the activated sensor electrode at least partially based on a real part and an imaginary part of a second current at the second terminal. Like the first voltage, the second voltage is normally a predefined voltage supplied by a second voltage source of the measurement device. The measurement device can measure the second current either at the second terminal or in some other location that is equivalent. Since the second voltage is given, the real part and the imaginary part of the second current can be determined. Again, certain areas in a diagram relating the real part with the imaginary part can be associated with a specific sensor electrode (or with a combination of sensor electrodes). By comparing the values for the real part and the imaginary part of the second current with threshold values, the respective sensor electrode can be identified. Some areas, though, may be associated with a single sensor electrode as well as with a combination of sensor electrodes, which leads to ambiguities. However, such ambiguities can normally be resolved when considering the measurements with respect to the first terminal. Likewise, when considering the real part and the imaginary part of the first current, some areas may also be associated with a single electrode as well as with a combination of two electrodes. These ambiguities can normally be resolved by taking into account the measurements at the second terminal. It is understood that alternatively, the second signal could be a current signal and the activated sensor electrode could be identified at least partially based on a real part and the imaginary part of a second voltage at the second terminal.

The invention in other embodiments also provides a method for capacitive position detection of an object, using a sensor line with a plurality of sensor electrodes connected in series, wherein at least one resistive element is effectively connected in series between each two consecutive sensor electrodes. The method comprises applying a time-dependent first signal via a linear, unbranched first connection to a first terminal of the sensor line and identifying an activated sensor electrode, with an object in its proximity, at least partially based on a first voltage-current relation at the first terminal. All these terms have been already mentioned above with respect to the inventive sensor arrangement and therefore will not be explained again. Preferred embodiments of the inventive method may correspond to those of the inventive sensor arrangement. The method steps can be performed by a measurement device connected to the first terminal as described above. In particular, the first signal can be applied by a first electric source of the measurement device via the first connection.

### BRIEF DESCRIPTION OF THE DRAWINGS

Further details and advantages of the present invention will be apparent from the following detailed description of not limiting embodiments with reference to the attached drawing, wherein:

FIG. 1 is a schematic view of a first embodiment of an inventive sensor arrangement;

FIG. 2 is a diagram showing a relation between a real part and an imaginary part of a first current;

FIG. 3 is a schematic view of a second embodiment of an inventive sensor arrangement;

FIG. 4 is a diagram showing a relation between a real part and an imaginary part of a first current; and

FIG. 5 is a diagram showing a relation between a real part and an imaginary part of a second current.

### DETAILED DESCRIPTION

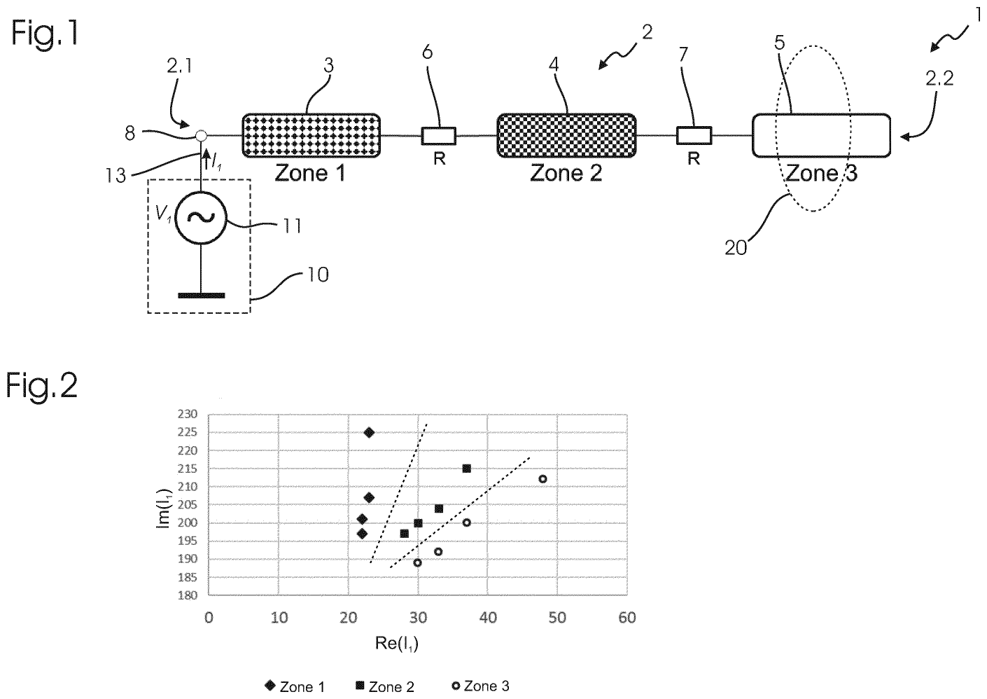

FIG. 1 schematically shows a first embodiment of an inventive sensor arrangement 1, which may be used e.g. for hand position detection on a steering wheel. The sensor arrangement 1 comprises a sensor line 2 comprising a first, second and third sensor electrode 3, 4, 5 connected in series. The sensor electrodes 3, 4, 5 could be associated with three zones (“zone 1”, “zone 2”, “zone 3”) of a surface of the steering wheel. A first resistor 6 is connected in series between the first sensor electrode 3 and the second sensor electrode 4, while a second resistor 7 is connected in series between the second sensor electrode 4 and the third sensor electrode 5. In the embodiment shown, the first and second resistor 6, 7 have an identical resistance R.

A measurement device 10 is connected via a linear, unbranched first connection 13 to a first terminal 8 of the sensor line 2. The first terminal 8 is an end terminal, i.e. it is disposed a first end 2.1 of the sensor line 2. The measurement device 10 comprises a first voltage source 11 that is adapted to apply a predetermined sinusoidal first voltage V₁ as a first signal to the first terminal 8. Specifically, the first voltage source 11 is connected to the first terminal 8 via the first connection 13. The measurement device 10 is also adapted to measure a first current I₁ through the first terminal 8.

As the first voltage V₁ is applied to the sensor line 2, the sensor electrodes 3, 4, 5 are charged with alternating polarity, while an electric field is formed between each sensor electrode 3, 4, 5 and ground (e.g. a grounded structure of the vehicle). If an object 20, like a hand of a user, is disposed in proximity e.g. to the third sensor electrode 5, the electric field and therefore the capacitance of the third sensor electrode 5 is changed. More specifically, the coupling of this third sensor electrode 5 to ground is considerably increased. This third sensor electrode 5 is now considered as an “activated” sensor electrode.

In order to determine a position of the object 20, the measurement device 10 has to identify the activated sensor electrode 5. This identification is based on a voltage-current relation at the first terminal 8. Since the first voltage V₁ is in this case predetermined by the first voltage source 11, it is sufficient to consider the first current I₁ through the first terminal 8. If the first voltage V₁ was not predetermined, it could be measured and the first current I₁ could be normalized (e.g. by dividing through the amplitude of the first voltage V₁).

FIG. 2 is a diagram showing the real part of the first current I₁ as the abscissa and the imaginary part of the first current I₁ as the ordinate. The diagram shows different measurements relating to an activation of the first sensor electrode 3 (solid diamond, “zone 1”), the second sensor electrode 4 (solid square, “zone 2”) and the third sensor electrode 5 (empty circle, “zone 3”), respectively. This is due to the fact that a current flowing between the first terminal 8 and the respective activated sensor electrode 3, 4, 5 flows through a different number of resistors 6, 7 depending on which sensor electrode 3, 4, 5 is activated. This, in turn, influences the total resistance of the sensor line 2, even if the reactance is more or less independent of which sensor electrode 3, 4, 5 is activated. The measurements refer to a situation where the object 20 is in the proximity of only one sensor electrode 3, 4, 5 at a time. In this case, it is evident that the measurements relating to the different zones can be distinguished clearly since they can be separated e.g. by the dashed lines in FIG. 2, which correspond to threshold values for the imaginary part or the real part, respectively. The threshold value for the imaginary part, for instance, is a function of the real part. The threshold values may be calculated by the measurement device 10 according to some formula or they may be read from a lookup table. By comparison of the measured values with the threshold values, the measurement device 10 can identify the activated sensor electrode 3, 4, 5.

If, however, two sensor electrodes 3, 4, 5 are activated simultaneously, measurements can become ambiguous as to the identification of the activated sensor electrode 3, 4, 5. For example, the measurements relating to an object 20 being simultaneously in the proximity of the first electrode 3 and the third electrode 5 lead to similar currents as those relating to the object 20 being in the proximity of the second electrode 4.

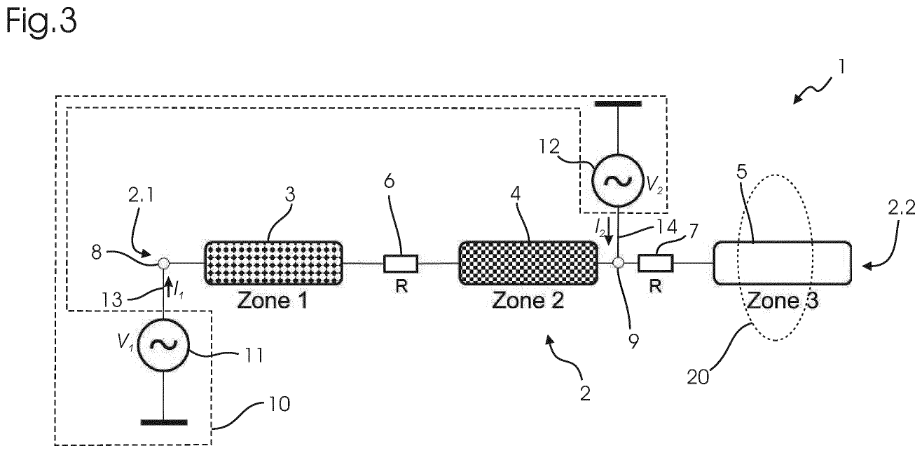

These ambiguities can be resolved by a second embodiment of an inventive sensor arrangement 1 that is shown in FIG. 3. This embodiment is largely identical to the one shown in FIG. 1, but the measurement device 10 further comprises a second voltage source 12 that is connected via a linear, unbranched second connection 14 to a second terminal 9 of the sensor line 2. The second terminal 9 is disposed between the second sensor electrode 4 and the third sensor electrode 5, or more specifically between the second sensor electrode 4 and the second resistor 7, so that the first and second terminal 8, 9 are disposed asymmetrically on the sensor line 2. In other words, while there is no sensor electrode between the first terminal 8 and the first end 2.1 of the sensor line 2, there is one sensor electrode between the second terminal 9 and the second end 2.2 of the sensor line 2.

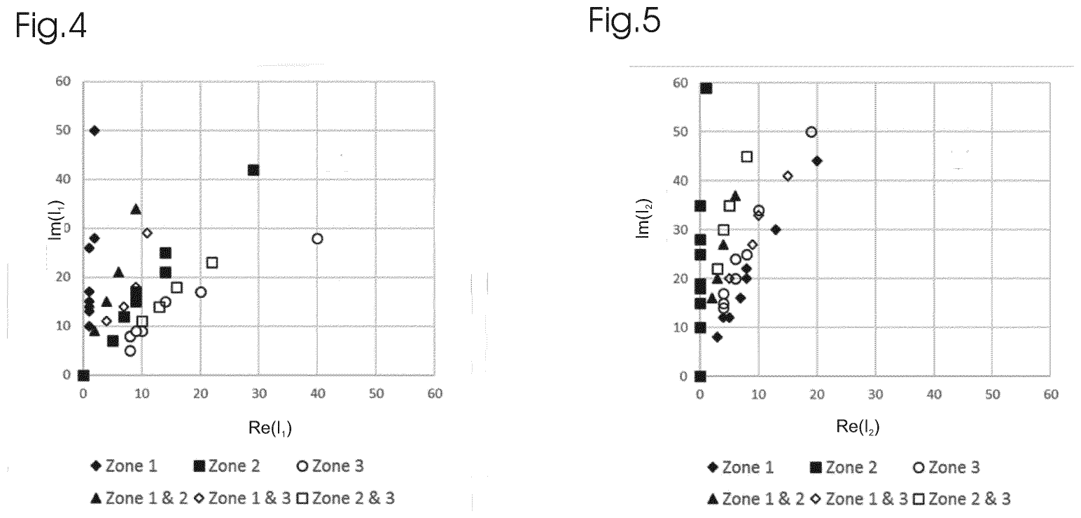

In one step, the measurement device 10 can apply the first voltage V₁ to the first terminal 8 and measure the first current I₁ as described above. The corresponding diagram relating the real part and the imaginary part of the first current I₁ is shown in FIG. 4. As mentioned above, the results can be ambiguous, for example when regarding the measurements referring to an activation of the second sensor electrode 4 alone (solid square, “zone 2”) and those referring to a simultaneous activation of the first and third sensor electrode 3, 5 (empty diamond, “zone 1 & 3”).

In another step, which may be carried out before, after or simultaneously with the above-mentioned step, the measurement device 10 applies a second voltage V₂ as a second signal to the second terminal 9 and measures a second current 12 through the second terminal 9. The second voltage V₂ is also a sinusoidal voltage having a predetermined amplitude and frequency, which may even be identical to those of the first voltage V₁. A diagram relating the real part to the imaginary part of the second current I₂ is shown in FIG. 5. Although this diagram alone also comprises some ambiguities, it resolves the ambiguities of the diagram in FIG. 4 and vice versa. For example, the measurements referring to an activation of the second sensor electrode 4 alone (solid square, “zone 2”) and those referring to a simultaneous activation of the first and third sensor electrode 3, 5 (empty diamond, “zone 1 & 3”) are clearly separated in FIG. 5. On the other hand, while the measurements referring to a simultaneous activation of the first and second electrode 3, 4 (solid triangle, “zone 1 & 2”) and those referring to a simultaneous activation of the second and third electrode 3, 5 (empty square, “zone 2 & 3”) are in the same area in FIG. 5, they are clearly separated in FIG. 4. Therefore, the embodiment shown in FIG. 3 allows for a reliable identification of an object 20 in the proximity of only one sensor electrode 3, 4, 5 as well as an object 20 (or two objects, respectively) simultaneously in the proximity of two sensor electrodes 3, 4, 5.

1. A sensor arrangement for capacitive position detection of an object, comprising:
a sensor line with a plurality of sensor electrodes connected in series, wherein at least one resistive element is effectively connected in series between each two consecutive sensor electrodes,
a measurement device connected via a linear, unbranched first connection to a first terminal of the sensor line,
wherein the measurement device is configured to apply a time-dependent first signal to the first terminal and to identify an activated sensor electrode, with an object in its proximity, at least partially based on a first voltage-current relation at the first terminal.

2. A sensor arrangement according to claim 1, wherein the sensor arrangement is adapted for hand detection in a steering wheel of a vehicle.

3. A sensor arrangement according to claim 1, wherein the first terminal is an end terminal of the sensor line.

4. A sensor arrangement according to claim 1, wherein at least one resistive element is a resistor external to the sensor electrodes.

5. A sensor arrangement according to claim 1, wherein the resistances of all resistive elements differ by less than 20%.

6. A sensor arrangement according to claim 1, wherein the measurement device is configured to apply a first voltage as the first signal and to identify the activated sensor electrode at least partially based on a real part and an imaginary part of a first current at the first terminal.

7. A sensor arrangement according to claim 1, wherein the first signal is a sinusoidal signal.

8. A sensor arrangement according claim 1, wherein the measurement device is connected via a linear, unbranched second connection to a second terminal of the sensor line and is configured to apply a time-dependent second signal to the second terminal and to identify at least one activated sensor electrode at least partially based on a second voltage-current relation at the second terminal.

9. A sensor arrangement according to claim 8, wherein the second terminal is disposed between two sensor electrodes.

10. A sensor arrangement according to claim 8, wherein the first and second terminal are asymmetrically disposed on the sensor line.

11. A sensor arrangement according to claim 1, wherein the measurement device is configured to apply the first signal and the second signal sequentially and/or simultaneously.

12. A sensor arrangement according to claim 1, wherein the measurement device is configured to identify at least two activated sensor electrodes.

13. A sensor arrangement according to claim 1, wherein the measurement device is configured to apply a second voltage as the second signal and to identify the activated sensor electrode at least partially based on a real part and an imaginary part of a second current at the second terminal.

14. A method for capacitive position detection of an object, using a sensor line with a plurality of sensor electrodes connected in series, wherein at least one resistive element is effectively connected in series between each two consecutive sensor electrodes, wherein the method comprises:
applying a time-dependent first signal via a linear, unbranched first connection to a first terminal of the sensor line, and
identifying an activated sensor electrode, with an object in its proximity, at least partially based on a first voltage-current relation at the first terminal.
